(19) United States
(12) Patent Application Publication
(10) Pub. No.: US 2018/0301354 A1
(43) Pub. Date: Oct. 18, 2018

(54) METHOD FOR MANUFACTURING A CIRCUIT CARRIER

(71) Applicant: DANFOSS SILICON POWER GMBH, Flensburg (DE)

(72) Inventors: Frank Osterwald, Kiel (DE); Aylin Bicakci, Kiel (DE); Ronald Eisele, Surendorf (DE)

(21) Appl. No.: 15/574,040

(22) PCT Filed: Apr. 26, 2016
(86) PCT No.: PCT/EP2016/059236

§ 371 Date: Nov. 14, 2017

(30) Foreign Application Priority Data
May 18, 2015 (DE) 102015107712.4

(51) Int. Cl. H01L 21/56; H01L 21/48

(52) U.S. Cl. CPC H01L 21/565; H01L 23/142; H01L 21/4846

(57) ABSTRACT

A method for manufacturing a circuit carrier (100′) having a base plate (10), an organic insulating foil (20) arranged on the base plate (10) and a metal shaped body (30) arranged on the insulating foil (20), wherein the base plate (10), insulating foil (20) and metal shaped body (30) are connected to each other by applying a quasi-hydrostatic pressure acting from the top while maintaining an even insulating foil layer thickness.

### CROSS-REFERENCE TO RELATED APPLICATIONS

This application is a National Stage application of International Patent Application No. PCT/EP2016/059236, filed on Apr. 26, 2016, which claims priority to German Patent Application No. 102015107712.4, filed on May 18, 2015, each of which is hereby incorporated by reference in its entirety.

### TECHNICAL FIELD

The invention relates to a method for manufacturing a circuit carrier having a base plate, an organic insulating foil arranged on the base plate and a metal shaped body arranged on the insulating foil.

### BACKGROUND ART

Such circuit carriers are used as an alternative to circuit carriers with ceramic DCB substrates (DCB: Direct Copper Bonded) in the field of power electronics.

Bicakci, Eisele, Osterwald and Olesen could show that the use of the “die on leadframe” technology in connection with thermally conducting and electrically insulating organic insulating foils enables the further development of power modules with high power density (see Bicakci A, Eisele R, Osterwald F, Olesen K. Comparison between Organic and Ceramic Substrate Insulation. Electronics System-Integration Technology Conference (ESTC). 2014. Pages 178ff). It is an additional advantage that the structure of the circuit carrier can be made thinner that of power modules with DCB substrates.

Although the known organic insulation foils are easy to handle, the method conventionally applied for laminating an organic insulating foil on a base plate in the area around the metal shaped bodies leads to an insufficient connection of the foil to the base plate.

FIG. 1 schematically shows an exemplary circuit carrier according to the prior art. The conventional circuit carrier exhibits a base plate 10. Onto the base plate 10 an organic insulating foil 20 is laminated that exhibits thermally conducting and electrically insulating properties. On the top side of the insulating foil 20 several metal shaped bodies 30 are arranged that are formed as individual bodies or coherently formed as one single body and firmly connected to the insulating foil 20. The metal shaped bodies 30 may be a leadframe, for example, in particular a stamped, pressed or punched shape.

Around and adjacent to the metal shaped bodies 30, the insulating foil 20 can be observed to bulge. In addition, in the areas between the metal shaped bodies 30 (or the portions of one single metal shaped body 30) it can be observed that the lamination of the insulating foil 20 on the base plate 10 has been inadequately executed.

This defective lamination in the area between the metal shaped bodies 30 or the metal shaped body portions 30 supports crack initiation, humidity absorption and ultimately the loss of insulating strength of the insulating layer 20.

The deformation of the insulating foil 20 and its defective lamination onto the base plate 10 are due to the conventionally used method for connecting these components that is outlined in FIG. 2.

In fact, the base plate 10, insulating foil 20 and metal shaped body 30 are commonly placed on a lower die 400 and the elements are crimped with each other by an upper die 200 exerting pressure on the metal shaped bodies 30. Here the insulating foil 20 preferably exhibits self-adhesive properties that lead to a connection of the insulating foil 20 with the base plate 10 on the one hand and the insulating foil 20 with the metal shaped body 30 on the other hand. Otherwise a suitable connecting means, for example an adhesive will be used in addition between the previously mentioned components.

The problem is thus that the pressure conveyed via the metal shaped body/bodies 30 leads to bulging around the margins of the metal shaped bodies 30 and an inadequate a pressure acting on the insulating foil in the areas between the bodies 30.

Because the properties of the insulating foil 20 change during the laminating process, applying and laminating the insulating foil 20 over the entire surface area of the base plate 10 is not practical, since a subsequent connection of the metal shaped body cannot be performed due to the changed properties of an already-laminated insulating foil.

### SUMMARY

It is therefore the object of the invention to create a method for manufacturing a circuit carrier that enables an even connection of the insulating foil to the base plate with high insulating strength.

According to the invention a method for manufacturing a circuit carrier is thus provided, where the circuit carrier exhibits a base plate, an organic insulating foil arranged on the base plate and a metal shaped body arranged on the insulating foil.

The base plate in particular is a component of the circuit carrier, the component exhibiting a carrying function on the one hand and a function fulfilling heat dissipation or heat spreading on the other hand.

The organic insulating foil is—as it is known—thermally conductive, electrically insulating and exhibits a good adhesion to metallic surfaces.

The metal shaped body for example can be designed in the shape of a lead frame, in particular a stamped, pressed or punched metal shape.

The base plate, insulating foil and metal shaped body are then now connected according to the invention by applying a quasi-hydrostatic pressure acting from the top onto the circuit carrier. That is, by the application of a quasi-hydrostatic pressure acting from the metal body side of the circuit carrier and towards the base plate. By applying a quasi-hydrostatic pressure, the base plate, insulating foil and metal shaped body are connected to each other in a manner that insures, by the quasi-hydrostatic properties, that an even insulation foil layer thickness is maintained.

The quasi-hydrostatic pressure is applied by a cushion, in particular a silicone cushion.

The aforementioned laminating method for laminating the insulating foil to the base plate can preferably be advantageously combined with a sintering method for populating the metal shaped body. This is done simply by populating the metal shaped body with electronic components before applying the quasi-hydrostatic pressure. During populating, a suitable sintering material is applied at the same time that creates the connection between the electronic components and the metal shaped body.

By combining the laminating process with the sintering method, the principle disadvantage of the low thermal conductivity of organic insulating foils in comparison to ceramic insulating materials under the boundary condition of sufficient electrical insulating strength can be compensated for by utilizing the heat-spreading function of the lead-frame-type circuit carriers placed under the components by silver-sintering. The improved heat-spreading and the overcoming of a slightly higher thermal resistance per unit area result in a component cooling performance that is as least as good as the use of a DCB substrate.

For easier separation of the cushion used for creating the quasi-hydrostatic pressure from the laminated and, where appropriate, sintered assembly the arrangement of base plate, insulating foil, metal shaped body and, where appropriate, electronic components, is covered with a protective film before the quasi-hydrostatic pressure is applied.

The protective film may be a single layer of film, such as a PTFE foil such as Teflon, or it may be of a multi-layered or multi-ply construction, the one layer or ply of the protective film consisting of Teflon and another layer or ply consisting of Kapton. The Teflon layer or ply may, for example, have a thickness of 400 μm and the layer or ply of Kapton that is facing the electronic components may be 50 μm thick, so that the risk of 10 contamination of the electronic components with Teflon is reduced.

Now the manufacturing processes for a power module are particularly advantageous:

With the inventive method an even and complete connection of the insulating foil to the base plate is achieved that promotes a high thermal conductivity. In addition, no insulating foil material penetrates into the gaps between the metal shaped bodies or between two metal shaped body portions, as the sintering die cushion reaches into these gaps and transfers the pressure evenly onto the metal shaped bodies or metal shaped body portions and the insulating foil in the intermediate spaces. This creates a controlled even layer thickness (and insulating strength) of the evenly laminated setup. An observed delaminating in the prior art originating from the poorly connected insulating foil areas in the gaps is thus prevented effectively.

Also, the metal shaped bodies and, where appropriate, electronic components arranged thereon may be of different thickness. By utilizing the quasi-hydrostatic pressure effect the inventive method is able to balance differences in height in the setup of the circuit carrier.

### BRIEF DESCRIPTION OF THE DRAWINGS

The invention will be described in more detail with reference to an exemplary embodiment of particularly preferred design. In the drawings:

FIG. 3 shows the schematic setup of a circuit carrier manufactured using the inventive method;

FIG. 4 shows the arrangement of a circuit carrier according to the invention in an apparatus suitable for carrying out the inventive method;

FIG. 5 shows a schematic process of the method for manufacturing the circuit carrier by laminating;

FIG. 6 shows a schematic process of the preferred method for manufacturing the circuit carrier by laminating combined with sintering;

FIG. 7 shows a schematic process of the preferred method for manufacturing the circuit carrier by laminating combined with sintering and the use of a Teflon foil;

FIG. 8 shows the arrangement of a circuit carrier according to the invention in an apparatus suitable for carrying out the inventive method where a Teflon foil is arranged between the cushion and the circuit carrier before the application of quasi-hydrostatic pressure and

FIG. 9 shows the arrangement of a circuit carrier according to the invention in an apparatus suitable for carrying out the inventive method where a Teflon foil is arranged between the cushion and the circuit carrier during the application of quasi-hydrostatic pressure.

### DETAILED DESCRIPTION

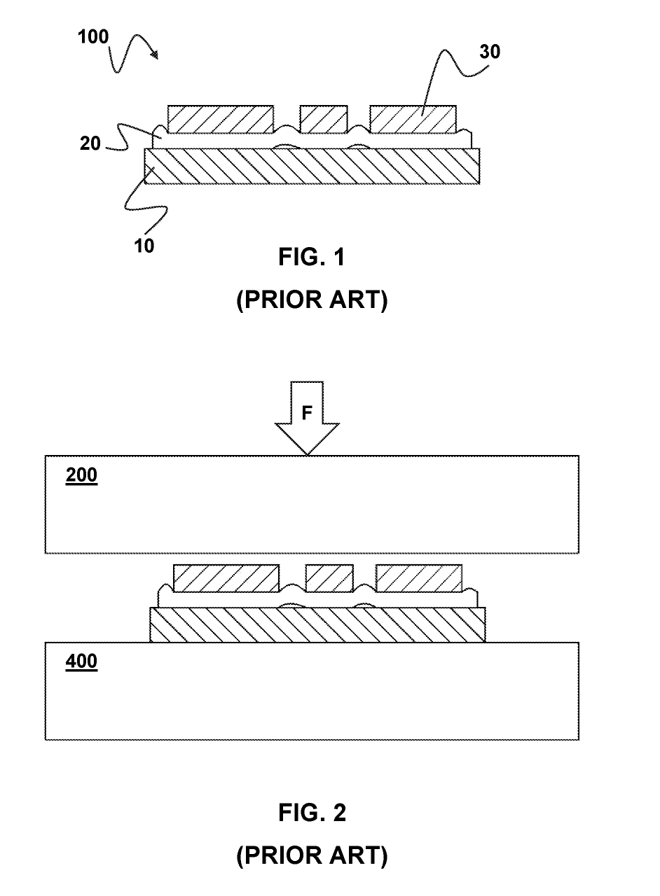

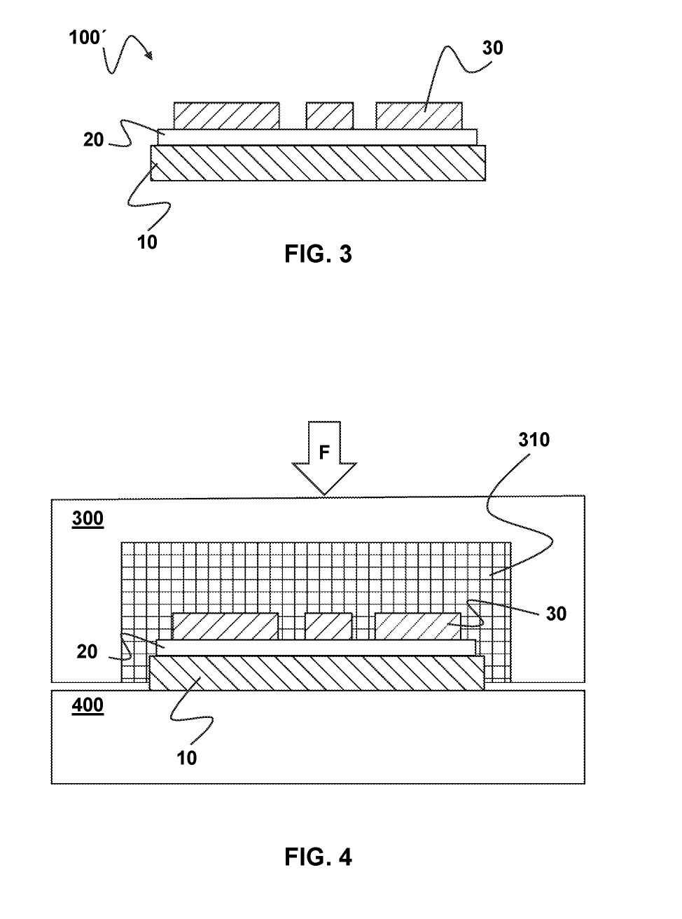

FIG. 3 shows the schematic setup of a circuit carrier manufactured with the inventive method. As is known, the circuit carrier 100′ exhibits a base plate 10, an insulating foil 20 and a metal shaped body 30.

In principle, the base plate 10, insulating foil and metal shaped body 30 have the properties known from the prior art. In order to avoid repetitions reference is made to the introduction mentioned above.

The difference achieved with regard to the prior art by means of the inventive method manifests itself in the layer thickness of the insulating foil 20 remaining even over the entire surface area of the insulating foil 20.

This different property of the product manufactured according to the invention is achieved by application of a quasi-hydrostatic pressure during the manufacturing process of the circuit carrier.

FIG. 4 shows an apparatus suitable for this purpose in a schematic view. Just like in the prior art, to manufacture the product shown in FIG. 3, a setup of a base plate 10, an insulating foil 20 arranged thereon and one metal shaped body or a plurality of bodies 30 with or without electronic components (40) is arranged on a lower die 400.

However, the apparatus is different from the apparatus used in the prior art in that the upper die 300 exhibits a cushion 310, preferably a silicone cushion 310. With the quasi-hydrostatic force transferred by the silicone cushion 310 an even insulating foil layer thickness—as described above—is achieved.

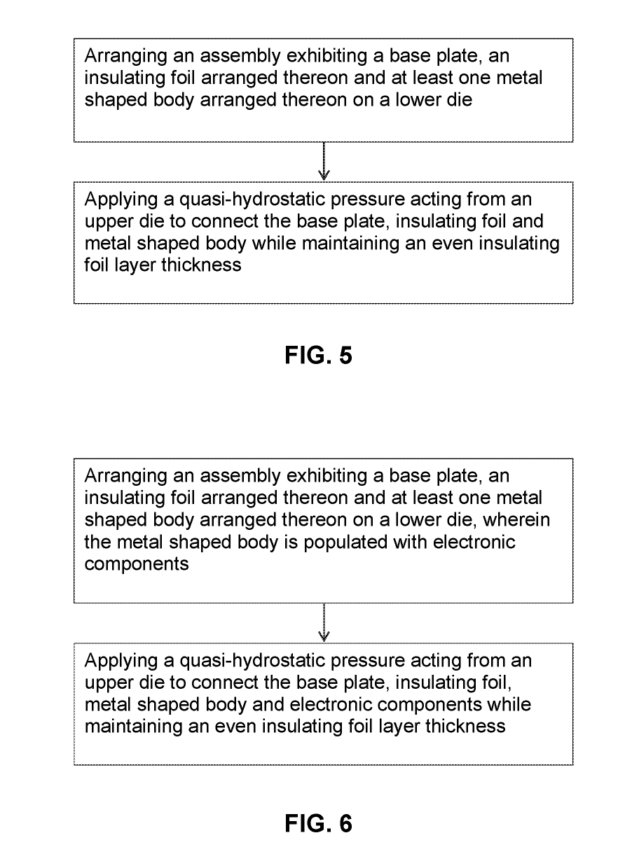

Furthermore, FIG. 5 shows the schematic process of the method for manufacturing the circuit carrier by laminating.

FIG. 6 shows the schematic process of the preferred method for manufacturing the circuit carrier by laminating combined with sintering.

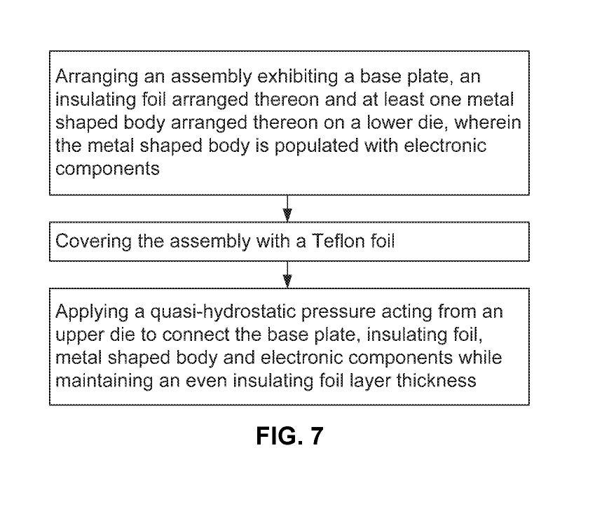

FIG. 7 shows a schematic process of the preferred method for manufacturing the circuit carrier by laminating combined with sintering and the use of a Teflon foil (50).

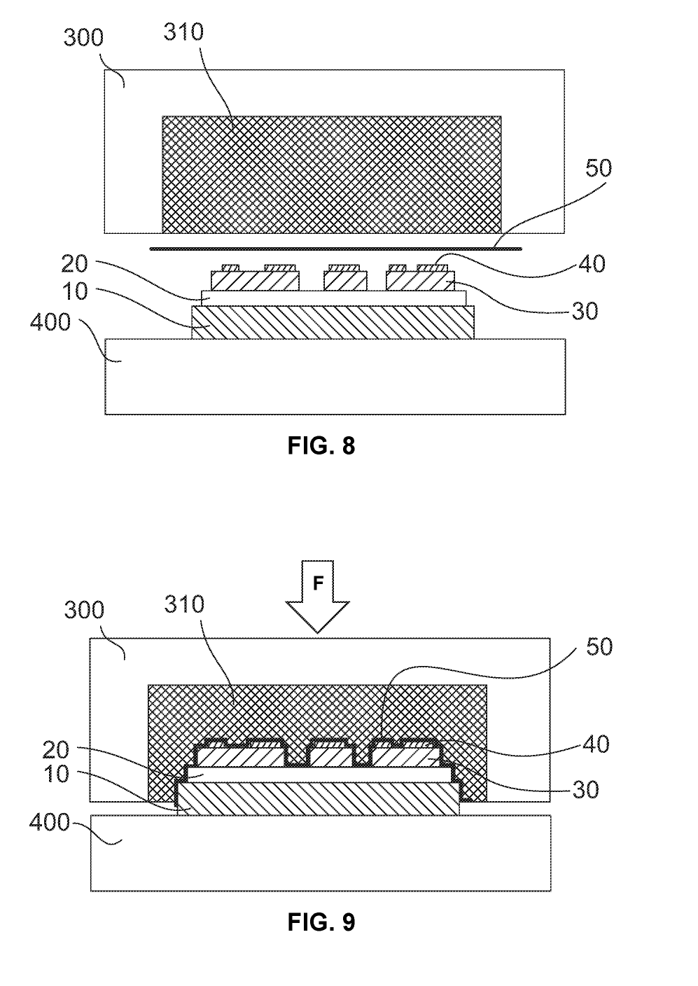

FIG. 8 shows the arrangement of a circuit carrier according to the invention in an apparatus suitable for carrying out the inventive method where a Teflon foil 50 is arranged between the cushion and the circuit carrier before the application of quasi-hydrostatic pressure. Here the metal shaped bodies 30 are populated with electronic components 40 and the Teflon foil 50 is arranged between the upper die 300 and the lower die 400.

FIG. 9 shows the arrangement of a circuit carrier according to the invention in an apparatus suitable for carrying out the inventive method where a Teflon foil 50 is arranged between the cushion and the circuit carrier during the application of quasi-hydrostatic pressure. The Teflon foil 50 now protects the circuit carrier, facilitating the release of the circuit carrier after the separation of the upper die 300 and the lower die 400.

What is claimed is:

1. A method for manufacturing a circuit carrier having a base plate, an organic insulating foil arranged on the base plate and a metal shaped body arranged on the insulating foil,
wherein
the base plate, insulating foil and metal shaped body are connected to each other by applying a quasi-hydrostatic pressure acting from the top while maintaining an even insulating foil layer thickness.

2. The method according to claim 1, wherein the metal shaped body is populated with electronic components before applying the quasi-hydrostatic pressure.

3. The method according to one of the claim 1, wherein the quasi-hydrostatic pressure is applied using a silicone cushion.

4. The method according to claim 1, wherein the arrangement of base plate, insulating foil, metal shaped body and, where appropriate, electronic components, is covered with a protective film before the quasi-hydrostatic pressure is applied.

5. The method according to one claim 1, wherein the protective film is a Teflon foil.

6. The method according to claim 2, wherein the quasi-hydrostatic pressure is applied using a silicone cushion.

7. The method according to claim 2, wherein the arrangement of base plate, insulating foil, metal shaped body and, where appropriate, electronic components, is covered with a protective film before the quasi-hydrostatic pressure is applied.

8. The method according to claim 3, wherein the arrangement of base plate, insulating foil, metal shaped body and, where appropriate, electronic components, is covered with a protective film before the quasi-hydrostatic pressure is applied.

9. The method according to one claim 2, wherein the protective film is a Teflon foil.

10. The method according to one claim 3, wherein the protective film is a Teflon foil.

11. The method according to one claim 4, wherein the protective film is a Teflon foil.
